(19) United States
(12) Patent Application Publication
(10) Pub. No.: US 2010/0300514 A1
(43) Pub. Date: Dec. 2, 2010

(54) SOLAR CELL AND METHOD FOR MANUFACTURING SOLAR CELL

(75) Inventors: Atsushi DENDA, Chino (JP); Hiromi SAITO, Chino (JP)

Correspondence Address: GLOBAL IP COUNSELORS, LLP, 1233 20TH STREET, NW, SUITE 700, WASHINGTON, DC, 20036-2680, US

(73) Assignee: SEIKO EPSON CORPORATION, Tokyo (JP)

(21) Appl. No.: 12/788,584

(22) Filed: May 27, 2010

(30) Foreign Application Priority Data
Jun. 2, 2009 (JP) 2009-132839

(51) Int. Cl. H01L 31/0224; H01L 31/18

(52) U.S. Cl. 136/252; 438/98; 257/E31.126

(57) ABSTRACT

A solar cell includes a substrate, a lower electrode layer, a semiconductor layer and an upper electrode layer. The lower electrode layer is formed on the substrate with the lower electrode layer having a first lower electrode layer and a second lower electrode layer. The first lower electrode layer includes a material having a lower electrical resistivity than the second lower electrode layer. The semiconductor layer is formed on the lower electrode layer. The upper electrode layer is formed on the semiconductor layer.

### CROSS-REFERENCE TO RELATED APPLICATIONS

This application claims priority to Japanese Patent Application No. 2009-132839 filed on Jun. 2, 2009. The entire disclosure of Japanese Patent Application No. 2009-132839 is hereby incorporated herein by reference.

### BACKGROUND

1. Technical Field

The present invention relates to a solar cell and to a method for manufacturing a solar cell.

2. Related Art

A solar cell converts light energy into electrical energy, and various types of configurations of solar cells have been proposed according to the semiconductor used. In recent years, CIGS-type solar cells have been emphasized for the simple manufacturing process thereof and the ability to realize high conversion efficiency. A CIGS solar cell is, for example, composed of a first electrode film formed on a substrate, a thin film that includes a compound semiconductor (copper-indium-gallium-selenide) formed on the first electrode film, and a second electrode film that is formed on the thin film. The second electrode film is formed in a groove formed by removing a portion of the thin film, and the first electrode film and second electrode film are electrically connected (see Japanese Laid-Open Patent Publication No. 2002-319686, for example).

### SUMMARY

In the solar cell described above, since the open-circuit voltage obtained by a single cell is low, a plurality of small-sized cells is connected in series to achieve modularization and increase the electromotive force. However, this modularization is accompanied by an increase in the current path (increase in series resistance), leading to the problem of loss of the current that flows through the conductive path.

The present invention was developed in order to overcome at least some of the problems described above, and the present invention can be implemented in the form of the embodiments or applications described below.

A solar cell according to a first aspect includes a substrate, a lower electrode layer, a semiconductor layer and an upper electrode layer. The lower electrode layer is formed on the substrate with the lower electrode layer having a first lower electrode layer and a second lower electrode layer. The first lower electrode layer includes a material having a lower electrical resistivity than the second lower electrode layer. The semiconductor layer is formed on the lower electrode layer. The upper electrode layer is formed on the semiconductor layer.

According to this configuration, the lower electrode layer is composed of a first lower electrode layer and a second lower electrode layer, and the first lower electrode layer is an electrode layer having a lower electrical resistivity than the second lower electrode layer. The lower electrode thus has a two-layer structure, and even when the second lower electrode layer of the lower electrode layers has a relatively high electrical resistivity, for example, supplementary incorporation of the first lower electrode layer having a low electrical resistivity makes it possible to lower the electrical resistivity of the lower electrode layer as a whole. Specifically, the sheet resistance of the lower electrode layer can be reduced. Loss of current flowing through the solar cell can thereby be reduced.

In the solar cell as described above, the first lower electrode layer is preferably formed on the substrate and includes silver or a compound having silver as a primary component, and the second lower electrode layer is preferably formed on the first lower electrode layer and includes molybdenum.

According to this configuration, the first lower electrode layer is formed using silver or a compound having silver as a primary component on the substrate, and the second lower electrode layer composed of molybdenum is formed on the first lower electrode layer. In a CIGS solar cell, for example, molybdenum is used as the material for forming the lower electrode layer. The reason that molybdenum is used in the lower electrode layer is described hereinafter. In the process for manufacturing the semiconductor layer (CIGS) of a CIGS-type solar cell, a laminate precursor composed of a copper-gallium (Cu—Ga) alloy layer and an indium (In) layer is formed on the molybdenum of the lower electrode layer, and the semiconductor layer (CIGS) is formed by heating (selenizing) the laminate precursor in a hydrogen selenide atmosphere. However, when the material of the lower electrode layer readily forms an alloy with selenium, for example, in the selenizing process, the formation of an alloy results in expansion of the semiconductor layer, and this expansion can cause cracking, peeling, and other adverse effects in the semiconductor layer. Molybdenum, which has excellent selenium resistance, is therefore used as the material for forming the lower electrode layer. However, the sheet resistance of the lower electrode layer is dependent on the electrical characteristics of molybdenum. Therefore, in the present invention, silver or a compound primarily composed of silver, which has lower electrical resistivity than molybdenum, is used to form the first lower electrode layer, and the first lower electrode layer together with the molybdenum-containing second lower electrode layer constitute the lower electrode layer. The sheet resistance of the lower electrode layer can thereby be reduced.

In the solar cell as described above, the first lower electrode layer preferably has indentations.

According to this configuration, since the first lower electrode layer has indentations, light that reaches the first lower electrode layer from among the light incident on the solar cell is scattered by the indentations and absorbed by the semiconductor layer. Specifically, the light capturing effects are enhanced. The conversion efficiency of the solar cell can therefore be enhanced.

In the solar cell as described above, the first lower electrode layer is preferably a nanowire layer formed on the substrate and includes silver or carbon as a primary component, and the second lower electrode layer is preferably formed on the first lower electrode layer and includes molybdenum.

According to this configuration, a nanowire layer primarily comprising carbon or silver, which has lower electrical resistivity than molybdenum, is used for the first lower electrode layer; and using this first lower electrode layer to constitute the lower electrode layer together with the molybdenum-containing second lower electrode layer enables the sheet resistance of the lower electrode layer as a whole to be reduced.

In the solar cell as described above, the substrate is preferably a transparent substrate, the first lower electrode layer is preferably formed in a grid or line pattern on the substrate and preferably includes silver or a compound having silver as a primary component, and the second lower electrode layer is preferably a transparent conductive member formed on the first lower electrode layer and the substrate.

According to this configuration, providing a transparent substrate and the lower electrode of a transparent conductive member enables light to be received from the side of the substrate surface. However, when the lower electrode is composed of a single layer, the sheet resistance of the lower electrode layer is dependent on the electrical characteristics of the transparent conductive member. Therefore, in the present invention, the first lower electrode layer is formed using silver or a compound primarily composed of silver, which has lower electrical resistivity than the transparent conductive member. The first lower electrode layer together with the second lower electrode layer formed by a transparent conductive member constitute the lower electrode layer. The sheet resistance of the lower electrode layer as a whole can thereby be reduced. Furthermore, since the first lower electrode layer is formed in a grid or line pattern, received light can be transmitted to the semiconductor layer without blocking the incidence of light, i.e., while maintaining light transmittance.

In the solar cell as described above, the substrate is preferably a transparent substrate, the first lower electrode layer is preferably a nanowire layer formed on the substrate and preferably includes silver or carbon as a primary component, and the second lower electrode layer is preferably a transparent conductive member formed on the first lower electrode layer and the substrate.

According to this configuration, a nanowire layer primarily comprising carbon or silver, which has lower electrical resistivity than the transparent conductive member, is used to form the first lower electrode layer; and using this first lower electrode layer together with the second lower electrode layer including the transparent conductive member to form the lower electrode layer enables the sheet resistance of the lower electrode layer as a whole to be reduced. Furthermore, by forming the nanowire layer so that an open area ratio for receiving light is ensured, the received light can be transmitted to the semiconductor layer without blocking the incidence of light.

A method for manufacturing a solar cell according to a second aspect includes: forming a lower electrode layer on a substrate by forming a first lower electrode layer on the substrate and forming a second lower electrode layer on the first lower electrode layer with the first lower electrode layer having a lower electrical resistivity than the second lower electrode layer; forming a semiconductor layer on the lower electrode layer; and forming an upper electrode layer on the semiconductor layer.

According to this configuration, the lower electrode layer is formed on the substrate. The lower electrode layer is composed of the first lower electrode layer and the second lower electrode layer, and in the first lower electrode layer formation step, an electrode layer is formed having a lower electrical resistivity than the second lower electrode layer. The lower electrode thus has a two-layer structure, and even when the second lower electrode layer of the lower electrode layers has a relatively high electrical resistivity, for example, supplementary incorporation of the first lower electrode layer having a low electrical resistivity makes it possible to lower the sheet resistance of the lower electrode layer as a whole. Loss of current flowing through the solar cell can thereby be reduced.

### BRIEF DESCRIPTION OF THE DRAWINGS

Referring now to the attached drawings which form a part of this original disclosure:

FIG. 1 is a view showing the solar cell according to a first embodiment, wherein FIG. 1(a) is a sectional view, and FIG. 1(b) is a partial enlarged sectional view;

FIG. 2 is a process view showing the method for manufacturing a solar cell according to the first embodiment;

FIG. 3 is a process view showing the method for manufacturing a solar cell according to the first embodiment;

FIG. 4 is a view showing the structure of the solar cell according to a second embodiment, wherein FIG. 4(a) is a sectional view, and FIGS. 4(b) and 4(c) are partial cutaway views;

FIG. 5 is a process view showing the method for manufacturing a solar cell according to the second embodiment; and

FIG. 6 is a process view showing the method for manufacturing a solar cell according to the second embodiment.

### DETAILED DESCRIPTION OF EXEMPLARY EMBODIMENTS

### First Embodiment

A first embodiment of the present invention will be described hereinafter with reference to the drawings. Each of the members shown in the drawings is shown sufficiently large to recognize, and members are not shown to scale in relation to each other.

### Structure of Solar Cell

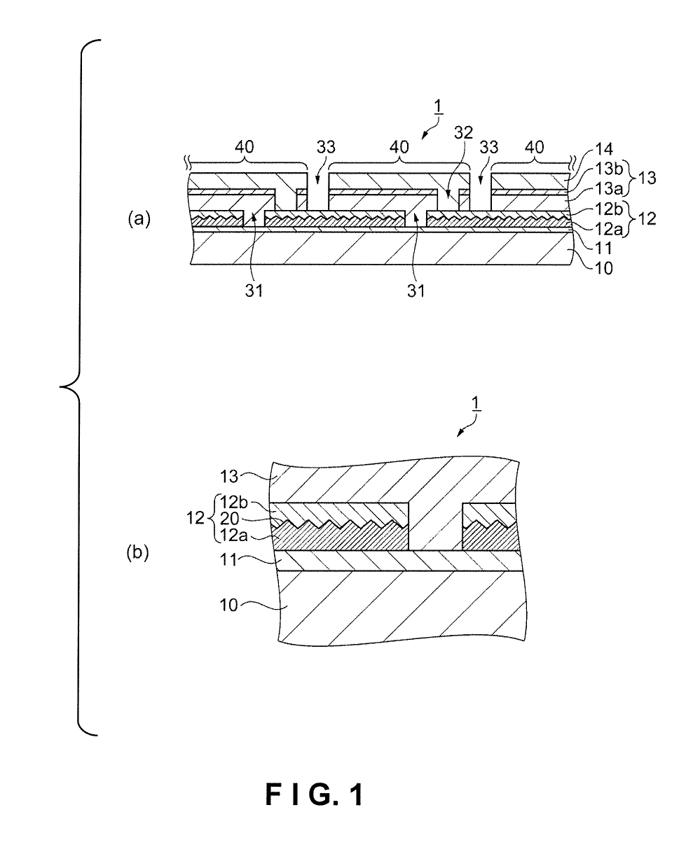

The structure of the solar cell (solar battery) will first be described. In the present embodiment, the structure of a CIGS-type solar cell will be described. FIG. 1 is a view showing the structure of the solar cell according to the present embodiment, wherein FIG. 1(a) is a sectional view, and FIG. 1(b) is a partial enlarged sectional view.

As shown in FIG. 1(a), the solar cell 1 is composed of an aggregate of cells 40 that are composed of a substrate 10; a base layer 11 formed on the substrate 10; a lower electrode layer 12 formed on the base layer 11; a semiconductor layer 13 formed on the lower electrode layer 12; and an upper electrode layer 14 formed on the semiconductor layer 13.

Adjacent cells 40 are divided from each other by third separating grooves 33. The lower electrode layer 12 is divided into cell 40 units by first dividing grooves 31, and is formed so as to bridge the spaces between adjacent cells 40. The lower electrode layer 12 and the upper electrode layer 14 are connected via second dividing grooves 32, and the upper electrode layer 14 of the cells 40 is connected to the lower electrode layer 12 of the other adjacent cells 40, whereby the cells 40 are each connected in series. The desired voltage in the solar cell 1 can thus be designed and changed to any value by appropriately setting the number of cells 40 that are connected in series.

The substrate 10 is a substrate in which at least the surface thereof on the side of the lower electrode layer 12 has insulating properties. Specific examples of substrates that can be used include glass (blue sheet glass or the like) substrates, stainless steel substrates, polyimide substrates, and mica substrates.

The base layer 11 is a layer having insulating properties and is formed on the substrate 10; an insulation layer primarily composed of SiO₂ (silicon dioxide), or an iron fluoride layer may be provided. The base layer 11 has insulating properties, and also has the function of maintaining adhesion between the substrate 10 and the lower electrode layer 12 formed on the substrate 10, and when the substrate 10 is composed of blue sheet glass, the base layer 11 has the function of preventing Na diffusion from the glass substrate to the lower electrode layer 12. The base layer 11 may be omitted when the substrate 10 has the characteristics described above.

The lower electrode layer 12 is composed of a first lower electrode layer 12a and a second lower electrode layer 12b. In the present embodiment, the first lower electrode layer 12a is formed on the substrate 10 (base layer 11), and the second lower electrode layer 12b is formed on the first lower electrode layer 12a. The first lower electrode layer 12a is formed using a material having lower electrical resistivity than the second lower electrode layer 12b. Specifically, when molybdenum, which has excellent resistance to selenization, is used in the second lower electrode layer 12b, the first lower electrode layer 12a is formed using a material having lower electrical resistivity than molybdenum, e.g., silver or a compound primarily composed of silver that includes copper, silicon, nickel, manganese, or the like. Using a material having low electrical resistivity in the first lower electrode layer 12a makes it possible to reduce resistance in the current path. Consequently, the first lower electrode layer 12a can be referred to as an auxiliary electrode layer that has the auxiliary function of reducing the sheet resistance of the lower electrode layer 12 as a whole.

The first lower electrode layer 12a is furthermore provided with indentations 20. In the present embodiment, numerous minute indentations 20 are formed close together in substantially the entire surface of the first lower electrode layer 12a in the direction of the semiconductor layer 13, as shown in FIG. 1(b). The indentations 20 have a surface roughness of 0.5 μm or greater, and are formed as pyramid shapes, triangular grooves, rectangular grooves, dots, a mesh, or a combination of these shapes. The dimensions, arrangement, and other characteristics of the indentations 20 may be uniform or random. Providing the indentations 20 causes light incident on the solar cell 1 to be scattered by the indentations 20, and the scattered light can be absorbed by the semiconductor layer 13. The conversion efficiency of the solar cell 1 can thereby be enhanced.

The semiconductor layer 13 is composed of a first semiconductor layer 13a and a second semiconductor layer 13b. The first semiconductor layer 13a is formed on the lower electrode layer 12, and is a p-type semiconductor layer (CIGS semiconductor layer) that includes copper (Cu), indium (In), gallium (Ga, and selenium (Se).

The second semiconductor layer 13b is formed on the first semiconductor layer 13a, and is a cadmium sulfide (CdS), zinc oxide (ZnO), indium sulfide (InS), or other n-type semiconductor layer.

The upper electrode layer 14 is a transparent electrode layer formed on the second semiconductor layer 13b, and is composed of ZnOAl or another transparent electrode (TCO: transparent conducting oxides), AZO, or the like.

When sunlight or other light is incident on the CIGS-type solar cell 1 configured as described above, electrons (−) and positive holes (+) occur in pairs in the semiconductor layer 13, and the electrons (−) collect in the n-type semiconductor, and the positive holes (+) collect in the p-type semiconductor at the joint surface between the p-type semiconductor layer (first semiconductor layer 13a) and the n-type semiconductor layer (second semiconductor layer 13b). As a result, an electromotive force occurs between the n-type semiconductor layer and the p-type semiconductor layer. In this state, a current can be taken off to the outside by connecting an external conductor to the lower electrode layer 12 and the upper electrode layer 14.

### Method for Manufacturing Solar Cell

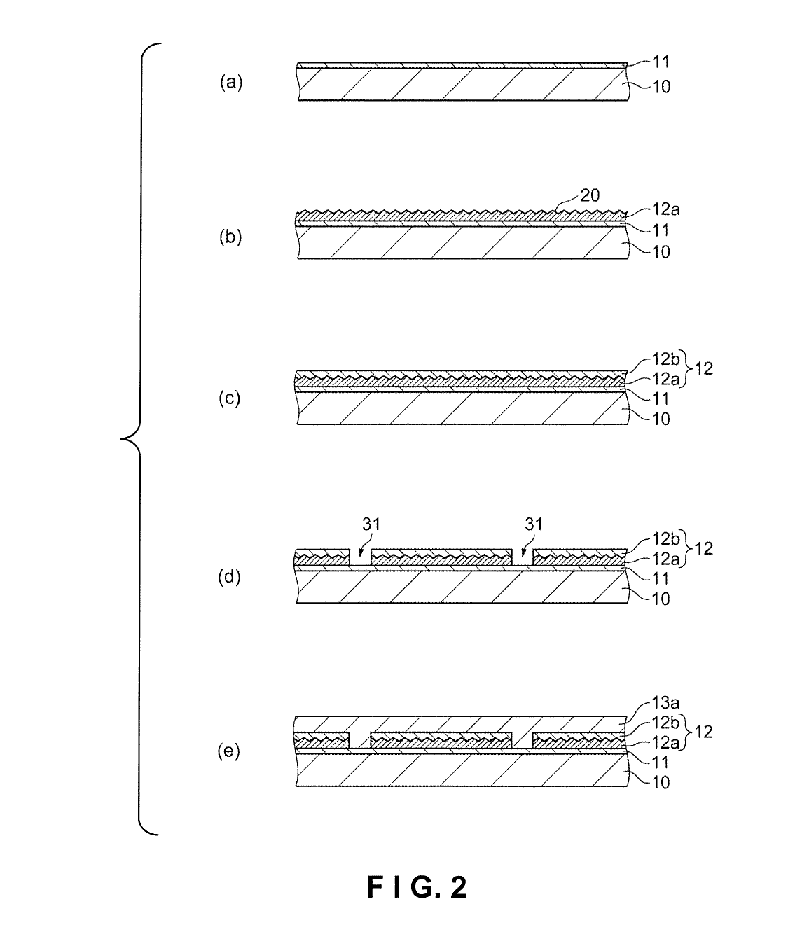

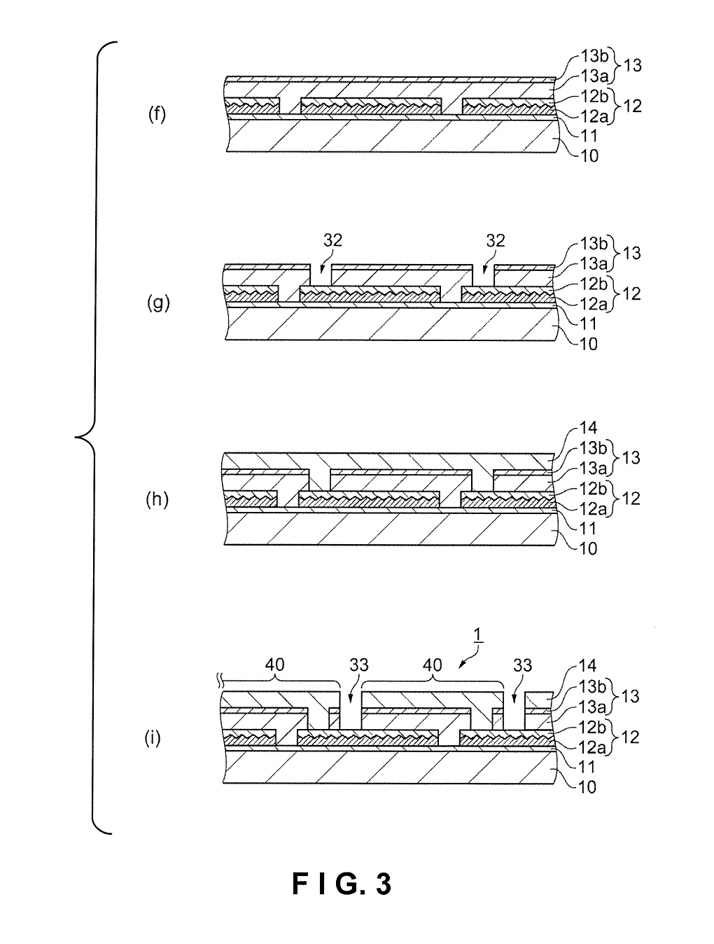

The method for manufacturing the solar cell will next be described. In the present embodiment, a method for manufacturing a CIGS-type solar cell will be described. FIGS. 2 and 3 are process views showing the method for manufacturing a solar cell according to the present embodiment.

In a base layer formation step shown in FIG. 2(a), the base layer 11 composed of SiO₂ is formed on one surface of a blue sheet glass or other glass substrate 10. The base layer 11 composed of SiO₂ can be formed on the glass substrate 10 by sputtering, CVD, or another method. The base layer 11 both prevents Na diffusion from the blue sheet glass substrate 10 to the lower electrode layer 12 and has the effect of increasing adhesion between the blue sheet glass substrate 10 and the lower electrode layer 12. The base layer formation step may be omitted when the glass substrate 10 has the functions of the base layer described above.

In a lower electrode layer formation step shown in FIGS. 2(b) and 2(c), the lower electrode layer 12 is formed on the glass substrate 10 on which the base layer 11 was formed. The lower electrode layer formation step includes a first lower electrode layer formation step and a second lower electrode layer formation step, and in the first lower electrode layer formation step shown in FIG. 2(b), the first lower electrode layer 12a is formed on the base layer 11. The second lower electrode layer 12b is then formed on the first lower electrode layer 12a in the second lower electrode layer formation step shown in FIG. 2(c).

In a first lower electrode layer formation step shown in FIG. 2(b), a layer of silver (Ag) as the first lower electrode layer 12a is formed on the 11 using sputtering, chemical vapor deposition, an inkjet method, a nano ink printing method, a printing method, or another method. Silver, as well as a compound primarily composed of silver that includes copper, silicon, nickel, manganese, or the like may be used as the material for forming the first lower electrode layer 12a.

In the first lower electrode layer formation step, the first lower electrode layer 12a is formed so as to have indentations 20. The indentations 20 have a surface roughness of 0.5 μm or greater, and are formed as pyramid shapes, triangular grooves, rectangular grooves, dots, a mesh, or a combination of these shapes. The dimensions, arrangement, and other characteristics of the indentations 20 may be uniform or random. The indentations 20 may be formed by a chemical or mechanical process after a flat-surfaced first lower electrode layer 12a is formed.

In a second lower electrode layer formation step shown in FIG. 2(c), a molybdenum (Mo) layer that will act as the second lower electrode layer 12b is formed on the first lower electrode layer 12a by sputtering. The lower electrode layer 12 composed of the first lower electrode layer 12a and second lower electrode layer 12b is thereby formed.

In a first division step shown in FIG. 2(d), a portion of the lower electrode layer 12 is removed by laser irradiation or another method, and the lower electrode layer 12 is divided in the thickness direction. The first dividing grooves 31 are formed where the lower electrode layer 12 was partially removed by laser irradiation or another method.

In a first semiconductor layer formation step shown in FIG. 2(e), copper (Cu), indium (In) and gallium (Ga) are deposited on the lower electrode layer 12 and in the first dividing grooves 31 by sputtering, and a precursor is formed. The precursor is then heated (selenized) in a hydrogen selenide atmosphere, and a p-type semiconductor layer (CIGS) to is formed act as the first semiconductor layer 13a.

In a second semiconductor layer formation step shown in FIG. 3(f), an n-type semiconductor layer to act as the second semiconductor layer 13b is formed using CdS, ZnO, InS, or the like on the first semiconductor layer 13a. The second semiconductor layer 13b can be formed by sputtering.

In a second division step shown in FIG. 3(g), a portion of the semiconductor layer 13 is removed by laser irradiation, a metal needle, or another method, and the semiconductor layer 13 is divided in the thickness direction. The second dividing grooves 32 are formed where the semiconductor layer 13 was partially removed by laser irradiation or another method.

In an upper electrode layer formation step shown in FIG. 3(h), the upper electrode layer 14 is formed on the semiconductor layer 13. For example, an AZO (Al-doped zinc oxide) or other transparent electrode (TCO) to act as the upper electrode layer is formed by sputtering or another method.

In a third division step shown in FIG. 3(i), portions of the upper electrode layer 14 and semiconductor layer 13 are removed by laser irradiation, a metal needle, or another method, and the upper electrode layer 14 and semiconductor layer 13 are divided in the thickness direction. The third separating grooves 33 are formed where the upper electrode layer 14 and semiconductor layer 13 were partially removed by laser irradiation or another method, and a single cell 40 is formed.

By the process described above, a CIGS-type solar cell 1 is formed in which a plurality of cells 40 is connected in series on the same glass substrate 10.

The effects described below are obtained through the first embodiment described above.

(1) A lower electrode layer 12 composed of a first lower electrode layer 12a and a second lower electrode layer 12b is formed on the substrate 10 (base layer 11). The second lower electrode layer 12b is an electrode layer that includes molybdenum (Mo), and the first lower electrode layer 12a is an electrode layer formed using a material (Ag or the like) having lower electrical resistivity than molybdenum. The first lower electrode layer 12a thereby contributes to lowering the electrical resistivity, and the sheet resistance of the lower electrode layer 12 as a whole can therefore be reduced. Loss of current flowing through the plurality of cells 40 can thereby be reduced, and a highly efficient solar cell 1 can be provided.

(2) Indentations 20 are formed on the surface of the first lower electrode layer 12a in the direction of the first semiconductor layer 13a. Since light that is incident on the solar cell 1 is thereby scattered by the indentations 20, and the scattered light is absorbed by the semiconductor layer 13, the conversion efficiency of the solar cell 1 can be enhanced.

### Second Embodiment

A second embodiment will next be described with reference to the drawings. Specifically, a description is provided of a CIGS-type solar cell that is capable of receiving light from both sides. Each of the members shown in the drawings is shown sufficiently large to recognize, and members are not shown to scale in relation to each other. The same reference numerals are also used to refer to each member.

### Structure of Solar Cell

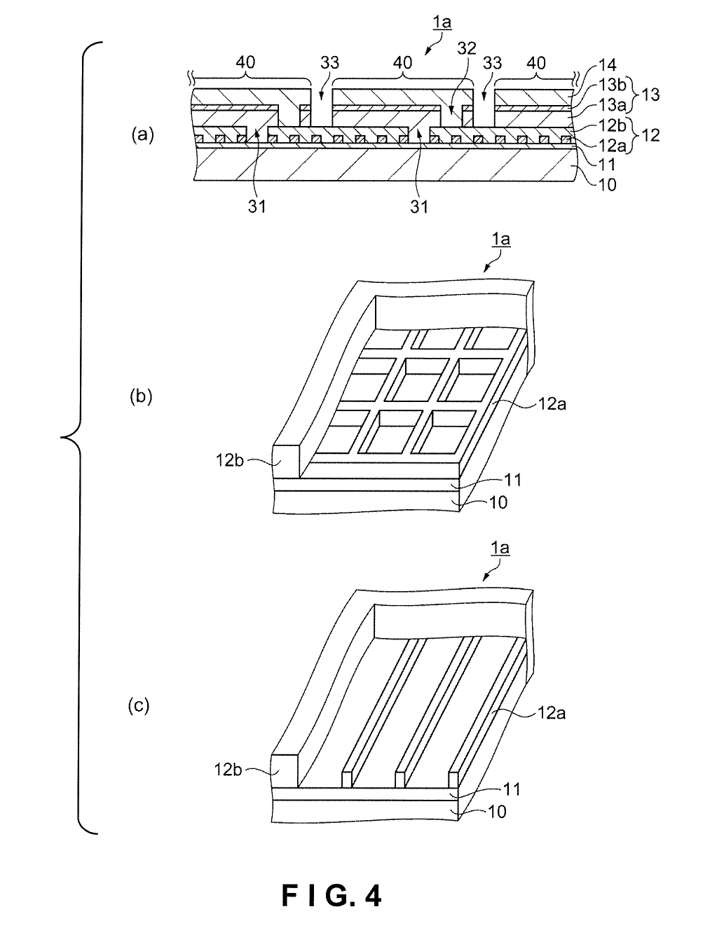

The structure of the solar cell will first be described. FIG. 4 is a view showing the structure of the solar cell according to the present embodiment, wherein FIG. 4(a) is a sectional view, and FIGS. 4(b) and 4(c) are partial cutaway views.

As shown in FIG. 4(a), the solar cell 1a is composed of an aggregate of cells 40 that are composed of a substrate 10; a base layer 11 formed on the substrate 10; a lower electrode. layer 12 formed on the base layer 11; a semiconductor layer 13 formed on the lower electrode layer 12; and an upper electrode layer 14 formed on the semiconductor layer 13. The structure between adjacent cells 40 and the method whereby the solar cell 1a operates are the same as in the first embodiment, and therefore will not be described.

The substrate 10 is a transparent substrate, and is a glass substrate, a PET substrate, an organic transparent substrate, or the like, for example. Using a transparent substrate enables light to be received from the surface of the substrate 10. In the present embodiment, a blue sheet glass substrate 10 is provided as the substrate.

The base layer 11 is a layer having insulating properties and that is formed on the blue sheet glass substrate 10; it is an insulation layer primarily composed of SiO₂ (silicon dioxide). The base layer 11 composed of SiO₂ may be formed on the glass substrate 10 by sputtering, CVD, or another method. The base layer 11 both prevents Na diffusion from the blue sheet glass substrate 10 to the lower electrode layer 12 and has the effect of increasing adhesion between the blue sheet glass substrate 10 and the lower electrode layer 12. The base layer 11 may be omitted when the blue sheet glass substrate 10 has the characteristics described above.

The lower electrode layer 12 is composed of a first lower electrode layer 12a and a second lower electrode layer 12b. In the present embodiment, the first lower electrode layer 12a is formed on the blue sheet glass substrate 10 (base layer 11), and the second lower electrode layer 12b is formed on the first lower electrode layer 12a. The second lower electrode layer 12b is a transparent electrode layer, and is an AZO (Al-doped zinc oxide) or other transparent electrode (TCO: transparent conducting oxides) layer, for example. Forming a transparent electrode layer enables light incident from the side of the blue sheet glass substrate 10 to pass through.

The first lower electrode layer 12a is formed by a material having lower electrical resistivity than the second lower electrode layer 12b. Specifically, a material such as silver, for example, having lower electrical resistivity than the transparent electrode (TCO) of the second lower electrode layer 12b can be used. Examples of other materials that can be used include compounds primarily composed of silver that include copper, silicon, nickel, manganese, and the like. Using a material having low electrical resistivity makes it possible to lower the electrical resistivity of the first lower electrode layer 12a. As a result, the sheet resistance of the lower electrode layer 12 can be reduced. Consequently, the first lower electrode layer 12a can be referred to as an auxiliary electrode layer that has the auxiliary function of reducing the sheet resistance of the lower electrode layer 12.

Furthermore, as shown in FIG. 4(b), the first lower electrode layer 12a has a grid shape. This configuration is adopted in order to enable light incident from the direction of the blue sheet glass substrate 10 to be effectively transmitted. The grid-shaped first lower electrode layer 12a is therefore preferably formed so as to have an open area ratio of 90% or higher to allow light to pass through. A first lower electrode layer 12a in a line pattern may also be formed, as shown in FIG. 4(c). Light that is incident from the direction of the blue sheet glass substrate 10 can be transmitted through this configuration as well. The first lower electrode layer 12a in a line pattern is also formed in this case so as to have an open area ratio of 90% or higher to allow light to pass through.

The semiconductor layer 13 is composed of a first semiconductor layer 13a and a second semiconductor layer 13b; the first semiconductor layer 13a is formed on the lower electrode layer 12, and is a p-type semiconductor layer (CIGS semiconductor layer) that includes copper (Cu), indium (In), gallium (Ga, and selenium (Se).

The second semiconductor layer 13b is formed on the first semiconductor layer 13a, and is a cadmium sulfide (CdS), zinc oxide (ZnO), indium sulfide (InS), or other n-type semiconductor layer.

The upper electrode layer 14 is a transparent electrode layer, and is composed of AZO (Al-doped zinc oxide) or another transparent electrode (TCO: transparent conducting oxides).

In the CIGS-type solar cell 1a configured as described above, light can be received from both the surface of the upper electrode layer 14 and the surface on the side of the blue sheet glass substrate 10.

### Method for Manufacturing Solar Cell

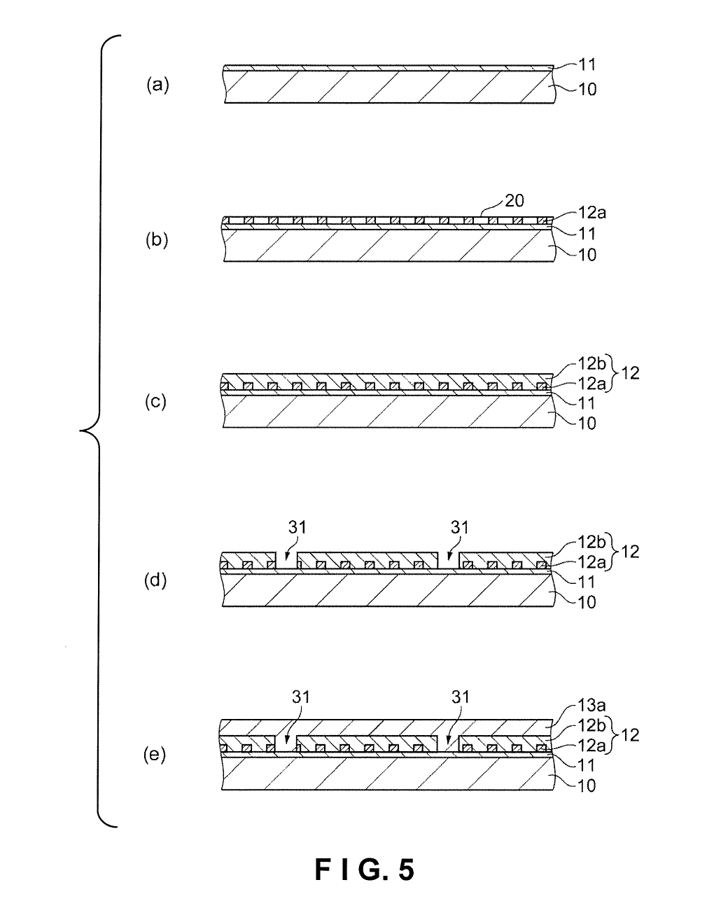

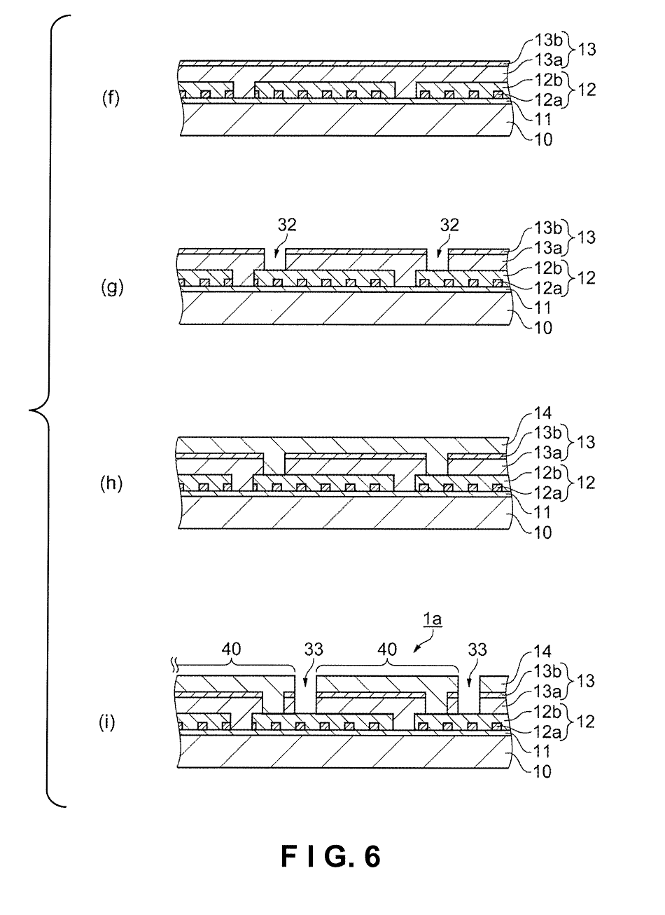

The method for manufacturing the solar cell will next be described. In the present embodiment, a method for manufacturing a CIGS-type solar cell capable of receiving light from both sides will be described. FIGS. 5 and 6 are process views showing the method for manufacturing a solar cell according to the present embodiment.

In a base layer formation step shown in FIG. 5(a), the base layer 11 composed of SiO₂ is formed on one surface of the blue sheet glass substrate 10. The base layer 11 composed of SiO₂ can be formed on the glass substrate 10 by sputtering, CVD, or another method. The base layer 11 both prevents Na diffusion from the blue sheet glass substrate 10 to the lower electrode layer 12 and has the effect of increasing adhesion between the blue sheet glass substrate 10 and the lower electrode layer 12. The base layer formation step may be omitted when the blue sheet glass substrate 10 has the effects of the base layer described above.

In a lower electrode layer formation step shown in FIGS. 5(b) and 5(c), the lower electrode layer 12 is formed on the blue sheet glass substrate 10 on which the base layer 11 was formed. The lower electrode layer formation step includes a first lower electrode layer formation step and a second lower electrode layer formation step, and in the first lower electrode layer formation step shown in FIG. 5(b), the first lower electrode layer 12a is formed on the base layer 11. The second lower electrode layer 12b is then formed on the first lower electrode layer 12a in the second lower electrode layer formation step shown in FIG. 5(c).

In a first lower electrode layer formation step shown in FIG. 5(b), a layer of silver (Ag) as the first lower electrode layer 12a is formed on the base layer 11 using sputtering, chemical vapor deposition, an inkjet method, a nano ink printing method, a printing method, or another method. Other materials that may be used to form the first lower electrode layer 12a include compounds primarily composed of silver that include copper, silicon, nickel, manganese, or the like.

Furthermore, in the first lower electrode layer formation step, the first lower electrode layer 12a is formed in a grid or line pattern as shown in FIG. 4(b) or 4(c). The first lower electrode layer 12a is formed so as to have an open area ratio of 90% or higher for transmitting light in order to ensure light reception from the side of the blue sheet glass substrate 10.

In a second lower electrode layer formation step shown in FIG. 5(c), the transparent second lower electrode layer 12b is formed on the first lower electrode layer 12a. An AZO (Al-doped zinc oxide) or other transparent electrode (TCO), for example, may be formed by sputtering or another method. The lower electrode layer 12 composed of the first lower electrode layer 12a and the second lower electrode layer 12b is thereby formed.

In a first division step shown in FIG. 5(d), a portion of the lower electrode layer 12 is removed by laser irradiation or another method, and the lower electrode layer 12 is divided in the thickness direction. The first dividing grooves 31 are formed where the lower electrode layer 12 was partially removed by laser irradiation or another method.

In a first semiconductor layer formation step shown in FIG. 5(e), copper (Cu), indium (In) and gallium (Ga) are deposited on the lower electrode layer 12 and in the first dividing grooves 31 by sputtering, and a precursor is formed. The precursor is then heated (selenized) in a hydrogen selenide atmosphere, and a p-type semiconductor layer (CIGS) to is formed act as the first semiconductor layer 13a.

In a second semiconductor layer formation step shown in FIG. 6(f), an n-type semiconductor layer to act as the second semiconductor layer 13b is formed by CdS, ZnO, InS, or the like on the first semiconductor layer 13a. The second semiconductor layer 13b can be formed by sputtering.

In a second division step shown in FIG. 6(g), a portion of the semiconductor layer 13 is removed by laser irradiation, a metal needle, or another method, and the semiconductor layer 13 is divided in the thickness direction. The second dividing grooves 32 are formed where the semiconductor layer 13 was partially removed by laser irradiation or another method.

In an upper electrode layer formation step shown in FIG. 6(h), the upper electrode layer 14 is formed on the semiconductor layer 13. For example, an AZO (Al-doped zinc oxide) or other transparent electrode (TCO) to act as the upper electrode layer is formed by sputtering or another method.

In a third division step shown in FIG. 6(i), portions of the upper electrode layer 14 and semiconductor layer 13 are removed by laser irradiation, a metal needle, or another method, and the upper electrode layer 14 and semiconductor layer 13 are divided in the thickness direction. The third separating grooves 33 are formed where the upper electrode layer 14 and semiconductor layer 13 were partially removed by laser irradiation or another method, and a single cell 40 is formed.

By the process described above, a CIGS-type solar cell 1a is formed in which a plurality of cells 40 is connected in series, and light can be received both from the side of the blue sheet glass substrate 10 and the side of the upper electrode layer 14.

Consequently, the effects described below are obtained through the second embodiment in addition to the effects of the first embodiment.

(1) A lower electrode layer 12 composed of a first lower electrode layer 12a and a second lower electrode layer 12b is formed on the blue sheet glass substrate 10 (base layer 11). The second lower electrode layer 12b is composed of a transparent electrode (TCO), and the first lower electrode layer 12a is an electrode layer formed using a material (Ag or the like) having lower electrical resistivity than the transparent electrode (TCO). The first lower electrode layer 12a thereby contributes to lowering the electrical resistivity, and the sheet resistance of the lower electrode layer 12 as a whole can therefore be reduced. The first lower electrode layer 12a is also formed in a grid or line pattern. Light that is incident from the side of the blue sheet glass substrate 10 is thereby efficiently transmitted to the semiconductor layer 13. A highly efficient solar cell 1a can therefore be provided that is capable of receiving light from both sides thereof.

The present invention is not limited to the embodiments described above, and may include such modifications as those described below.

### Modification 1

In the embodiments described above, the first lower electrode layer 12a is formed using silver or a compound primarily composed of silver, but this configuration is not limiting. For example, the first lower electrode layer 12a may be a nanowire layer primarily comprising silver or carbon. When light is received from the side of the blue sheet glass substrate 10 as well, the abovementioned nanowire layer is formed so as to have an open area ratio of 90% or higher for transmitting light, so as to ensure the transmittance of light. The same effects as those described above can be obtained through this configuration as well.

Modification 2

In the first embodiment described above, indentations 20 are provided to the lower electrode layer 12, but the indentations 20 may also be formed by forming the first lower electrode layer 12a in a grid or line pattern as shown in FIGS. 4(b) and 4(c) of the second embodiment, for example. The same effects as those described above can be obtained through this configuration as well.

Modification 3

In the embodiments described above, the first lower electrode layer 12a was described as being applied to a CIGS-type solar cell, but this configuration is not limiting. For example, the first lower electrode layer 12a may be applied to the electrode layer structure in a CIS (copper-indium-selenide) solar cell or a thin film silicon solar cell. The sheet resistance of the electrode layer can easily be reduced by this configuration as well.

### GENERAL INTERPRETATION OF TERMS

In understanding the scope of the present invention, the term “comprising” and its derivatives, as used herein, are intended to be open ended terms that specify the presence of the stated features, elements, components, groups, integers, and/or steps, but do not exclude the presence of other unstated features, elements, components, groups, integers and/or steps. The foregoing also applies to words having similar meanings such as the terms, “including”, “having” and their derivatives. Also, the terms “part,” “section,” “portion,” “member” or “element” when used in the singular can have the dual meaning of a single part or a plurality of parts. Finally, terms of degree such as “substantially”, “about” and “approximately” as used herein mean a reasonable amount of deviation of the modified term such that the end result is not significantly changed. For example, these terms can be construed as including a deviation of at least ±5% of the modified term if this deviation would not negate the meaning of the word it modifies.

While only selected embodiments have been chosen to illustrate the present invention, it will be apparent to those skilled in the art from this disclosure that various changes and modifications can be made herein without departing from the scope of the invention as defined in the appended claims. Furthermore, the foregoing descriptions of the embodiments according to the present invention are provided for illustration only, and not for the purpose of limiting the invention as defined by the appended claims and their equivalents.

What is claimed is:

1. A solar cell comprising:
a substrate;
a lower electrode layer formed on the substrate with the lower electrode layer having a first lower electrode layer and a second lower electrode layer, the first lower electrode layer including a material having a lower electrical resistivity than the second lower electrode layer;
a semiconductor layer formed on the lower electrode layer; and
an upper electrode layer formed on the semiconductor layer.

2. The solar cell according to claim 1, wherein
the first lower electrode layer is formed on the substrate and includes silver or a compound having silver as a primary component, and
the second lower electrode layer is formed on the first lower electrode layer and includes molybdenum.

3. The solar cell according to claim 1, wherein
the first lower electrode layer has indentations.

4. The solar cell according to claim 1, wherein
the first lower electrode layer is a nanowire layer formed on the substrate and includes silver or carbon as a primary component, and
the second lower electrode layer is formed on the first lower electrode layer and includes molybdenum.

5. The solar cell according to claim 1, wherein
the substrate is a transparent substrate;
the first lower electrode layer is formed in a grid or line pattern on the substrate and includes silver or a compound having silver as a primary component, and
the second lower electrode layer is a transparent conductive member foamed on the first lower electrode layer and the substrate.

6. The solar cell according to claim 1, wherein
the substrate is a transparent substrate,
the first lower electrode layer is a nanowire layer formed on the substrate and includes silver or carbon as a primary component, and
the second lower electrode layer is a transparent conductive member formed on the first lower electrode layer and the substrate.

7. A method for manufacturing a solar cell comprising:
foaming a lower electrode layer on a substrate by forming a first lower electrode layer on the substrate and forming a second lower electrode layer on the first lower electrode layer with the first lower electrode layer having a lower electrical resistivity than the second lower electrode layer;
forming a semiconductor layer on the lower electrode layer; and
forming an upper electrode layer on the semiconductor layer.
